(19) United States
(12) Patent Application Publication
(10) Pub. No.: US 2017/0309589 A1
(43) Pub. Date: Oct. 26, 2017

(54) SEMICONDUCTOR DEVICE AND METHOD FOR MANUFACTURING THE SAME

(71) Applicant: ELECTRONICS AND TELECOMMUNICATIONS RESEARCH INSTITUTE, Daejeon (KR)

(72) Inventors: Myungjoon KWACK, Gimpo (KR); Gyungock KIM, Daejeon (KR); Jaegyu PARK, Incheon (KR); Jin Hyuk OH, Daejeon (KR); Jiho JOO, Sejong (KR)

(21) Appl. No.: 15/423,473

(22) Filed: Feb. 2, 2017

(30) Foreign Application Priority Data
Apr. 21, 2016 (KR) 10-2016-0048965

(51) Int. Cl. H01L 23/00; H01L 25/065

(52) U.S. Cl. CPC H01L 24/32; H01L 25/0657; H01L 24/83; H01L 2224/32111; H01L 2225/0651; H01L 2225/06517; H01L 2224/83191

(57) ABSTRACT

Provided are a semiconductor device and a method for manufacturing the same. The semiconductor device according to an embodiment of the inventive concept includes a first semiconductor chip having a recess portion in one surface thereof; a first adhesion pattern filled within the recess portion of the first semiconductor chip; and a second semiconductor chip disposed on the first adhesion pattern. The second semiconductor chip may represent improved heat dissipation characteristics.

### CROSS-REFERENCE TO RELATED APPLICATIONS

This U.S. non-provisional patent application claims priority under 35 U.S.C. §119 of Korean Patent Application No. 10-2016-0048965, filed on Apr. 21, 2016, the entire contents of which are hereby incorporated by reference.

### BACKGROUND

The present disclosure herein relates to a semiconductor device, and more particularly, to an adhesion pattern of a semiconductor device and a method for manufacturing the same.

Semiconductor packages realize integrated circuit chips into the forms that are appropriate to be used for electronic devices.

A semiconductor package is provided to implement an integrated circuit chip to be suitable for use in an electronic appliance. Generally in the semiconductor packages, a semiconductor chip is mounted on a printed circuit board (PCB) to electrically connect the PCB to the semiconductor chip by using a bonding wire and a bump. As the electronic industry is developed, the requirements of high performance, high speed, and miniaturization in electronic devices are increasing. In response to this trend, a method for stacking several semiconductor chips on one substrate comes to the fore. In a process for manufacturing the semiconductor package, wafer bonding technologies for bonding two semiconductor chips having lattice constants different from each other into one unit have attracted considerable attention. The wafer bonding may be performed through direct bonding or indirect bonding. The direct bonding may be performed at a high temperature. Also, pretreatment processes may be required before the direct bonding process. The indirect bonding may be simply performed at a lower temperature than the direct bonding. Therefore, the indirect bonding technologies have attracted considerable attention.

### SUMMARY

The present disclosure provides a semiconductor device having improved heat dissipation characteristic and a method for manufacturing the same.

Provided are a semiconductor device and a method for manufacturing the same. An embodiment of the inventive concept provides a semiconductor device including: a first semiconductor chip having a recess portion in one surface thereof; a first adhesion pattern filled within the recess portion of the first semiconductor chip; and a second semiconductor chip attached to the first semiconductor chip by the first adhesion pattern, wherein the first adhesion pattern is disposed between the first semiconductor chip and the second semiconductor chip.

In an embodiment, the second semiconductor chip may physically contact each of the first adhesion pattern and the first semiconductor chip.

In an embodiment, the first semiconductor chip may have a thermal conductivity greater than that of the first adhesion pattern.

In an embodiment, the first semiconductor chip may further include a metal pattern, wherein the recess portion is disposed within the metal pattern.

In an embodiment, the second semiconductor chip may physically contact the metal pattern and the first adhesion pattern.

In an embodiment, the semiconductor device may further include a metal layer interposed between the first adhesion pattern and the second semiconductor chip, wherein the metal layer has a thermal conductivity greater than that of the first adhesion pattern.

In an embodiment, the semiconductor device may further include a second adhesion pattern disposed on one surface of the first semiconductor chip and a side surface of the second semiconductor chip, wherein the second adhesion pattern comprises the same material as the first adhesion pattern.

In an embodiment, the recess portion may have a height of about 100 nm to about 10 μm.

In an embodiment, the semiconductor device may further include a substrate, wherein the first semiconductor chip is disposed on the substrate.

In an embodiment of the inventive concept provides a method for manufacturing a semiconductor device includes: preparing a first semiconductor chip having a recess portion in one surface thereof; forming an adhesion pattern within the recess portion; and disposing a second semiconductor chip on the first semiconductor chip and the adhesion pattern.

In an embodiment, the second semiconductor chip may contact each of the adhesion pattern and the first semiconductor chip, and the first semiconductor chip may have a thermal conductivity greater than that of the adhesion pattern.

In an embodiment, the preparing of the first semiconductor chip may include: forming a mask pattern on the one surface of the first semiconductor chip; and etching the first semiconductor chip exposed by the mask pattern to form the recess portion.

In an embodiment, the forming of the adhesion pattern may include applying the adhesion pattern on the first semiconductor chip to cover the one surface of the first semiconductor chip.

In an embodiment, the method may further include applying a pressure to the second semiconductor chip to allow a bottom surface of the second semiconductor chip to physically contact the one surface of the first semiconductor chip after the second semiconductor chip is disposed.

In an embodiment, the method further includes disposing the first semiconductor chip on a substrate.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a plan view of a semiconductor device according to embodiments of the inventive concept;

FIG. 1B is a cross-sectional view taken along line A-B of FIG. 1A;

FIG. 1C is a cross-sectional view taken along line A-B of FIG. 1A according to another embodiment of the inventive concept;

FIG. 1D is a cross-sectional view taken along line A-B of FIG. 1A according to another embodiment of the inventive concept;

FIGS. 2A and 2B are plan views of first adhesion patterns according to other embodiments;

FIG. 3A is a plan view of a semiconductor device according to another embodiment of the inventive concept;

FIG. 3B is a cross-sectional view taken along line A′-B′ of FIG. 3A;

FIG. 4A is a plan view of a semiconductor device according to another embodiment of the inventive concept;

FIG. 4B is a cross-sectional view taken along line A′-B′ of FIG. 4A;

FIG. 4C is a cross-sectional view taken along line A′-B′ of FIG. 4A according to another embodiment of the inventive concept;

FIGS. 5A to 5E are cross-sectional views taken along line A-B of FIG. 1A for illustrating a method for manufacturing a semiconductor device according to an embodiment;

FIG. 6 is a cross-sectional view of a semiconductor device according to another embodiment;

FIG. 7 is a cross-sectional view of a semiconductor device according to another embodiment;

FIGS. 8A to 8E are cross-sectional views illustrating a method for manufacturing a semiconductor device according to another embodiment;

FIGS. 9A and 9B are cross-sectional views for explaining a method for forming a recess portion according to another embodiment;

FIG. 10A is a plan view of a semiconductor package according to an embodiment of the inventive concept; and

FIG. 10B is a cross-sectional view taken along line A″-B″ of FIG. 10A.

### DETAILED DESCRIPTION

Preferred embodiments of the inventive concept will be described with reference to the accompanying drawings so as to sufficiently understand constitutions and effects of embodiments of the inventive concept. However, embodiments of the inventive concept are not limited to the embodiments set forth herein and may be embodied in different forms. Also, various modifications may be made. Rather, these embodiments are provided so that this disclosure will be thorough and complete and will fully convey the scope of the embodiment of the inventive concept to those skilled in the art. A person with ordinary skill in the technical field to which the embodiments of the inventive concept pertains will understand that the embodiment of the inventive concept can be carried out under any appropriate environments.

In the following description, the terms are used only for explaining specific exemplary embodiments while not limiting the embodiment of the inventive concept. In this specification, the terms of a singular form may include plural forms unless specifically mentioned. It will be understood that terms ‘comprises’ and/or ‘comprising’, when used in this specification, specify the presence of stated component, step, operation and/or element, but does not exclude the presence or addition of one or more other components, steps, operations and/or elements.

In the specification, it will be understood that when a film (or layer) is referred to as being ‘on’ another film (or layer) or a substrate, it can be directly on other film (or layer) or substrate, or an intervening film (or layer) may also be present therebetween.

Also, though terms like a first, a second, and a third are used to describe various regions and films (or layers) in various embodiments of the specification, the regions and the films should not be limited by these terms. These terms are used only to discriminate one region or film (or layer) from another region or layer film (or layer). Therefore, a layer referred to as a first layer in one embodiment can be referred to as a second layer in another embodiment. Each of the embodiments described and exemplified herein includes a complementary embodiment thereof. Like reference numerals refer to like elements throughout.

Unless otherwise defined, all terms used in the embodiments of the inventive concept have the same meaning as commonly understood by one of ordinary skill in the art to which the embodiment of the inventive concept pertains.

Hereinafter, a display device according to an embodiment of the inventive concept will be described.

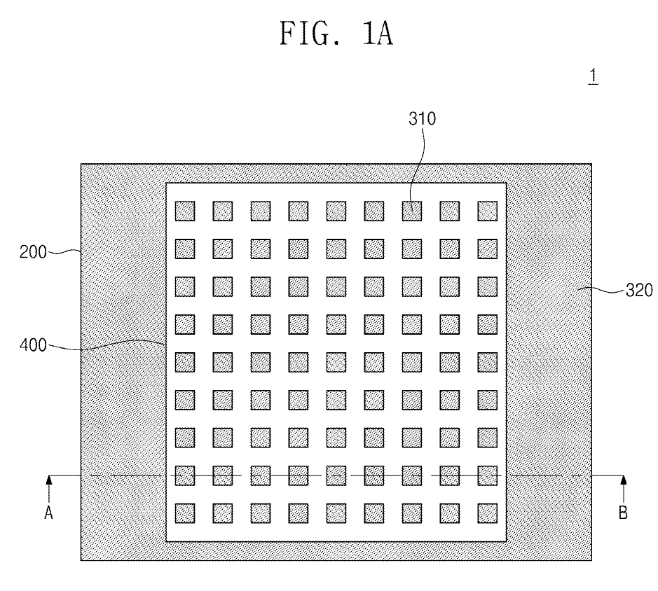

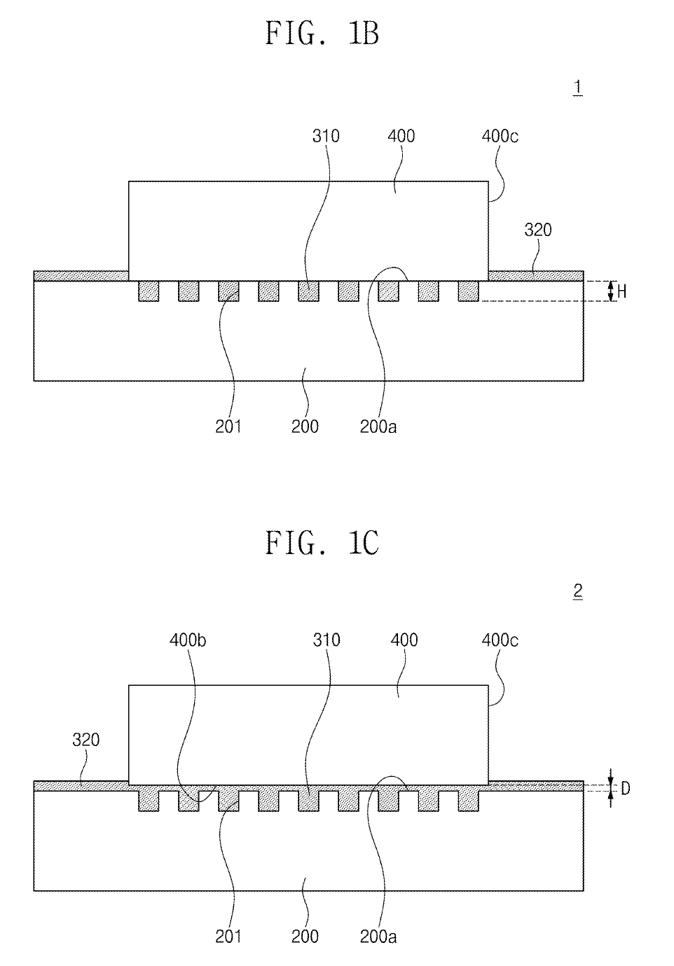

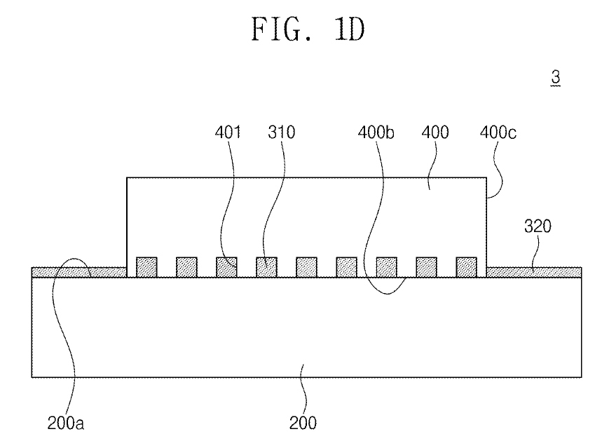

FIG. 1A is a plan view of a semiconductor device according to embodiments of the inventive concept. FIG. 1B is a cross-sectional view taken along line A-B of FIG. 1A.

Referring to FIGS. 1A and 1B, a semiconductor device 1 may include a first semiconductor chip 200, a first adhesion pattern 310, and a second semiconductor chip 400. The first semiconductor chip 200 may include bulk silicon, silicon on insulator (SOI), or III-V compound semiconductor. The first semiconductor chip 200 may have a thermal conductivity of about 149 W/mk (in the case of silicon). The first semiconductor 200 may include a logic circuit. A recess portion 201 may be provided in a top surface 200a of the first semiconductor chip 200. The recess portion 201 may have a height H of about 100 nm to about 10 μm.

The first adhesion pattern 310 may be provided within the recess portion 201. The first adhesion pattern 310 may be localized within the recess portion 201. For example, the first adhesion pattern 310 may not extend on the top surface 200a of the first semiconductor chip 200. The first adhesion pattern 310 may have a top surface disposed at the same or similar level as the top surface 200a of the first semiconductor chip 200. As illustrated in FIG. 1A, the first adhesion pattern 310 may have a rectangular shape in view of plane. The first semiconductor chip 310 may have a thermal conductivity of about 0.5 W/mK. The first adhesion pattern 310 may include a thermosetting material or a photocurable-material. For example, the first adhesion pattern 310 may include polymers such as polyimide or benzocyclobutene (BCB). For another example, the first adhesion pattern 310 may include spin on glass (SOG).

The second semiconductor chip 400 may be disposed on the first semiconductor chip 200 and the first adhesion pattern 310. The second semiconductor chip 400 may have a bottom surface that physically contacts the first adhesion pattern 310 and the first semiconductor chip 200. In view of plane, the second semiconductor chip 400 may overlap the first adhesion pattern 310. The second semiconductor chip 400 may be attached to the first semiconductor chip 200 by the first adhesion pattern 310. The second semiconductor chip 400 may be an optical chip, an image sensor chip, or a memory chip. When the semiconductor device 1 operates, heat may be generated from the second semiconductor chip 400. The first semiconductor chip 200 may have a thermal conductivity greater than that of the first adhesion pattern 310. Since the second semiconductor chip 400 physically contacts the first semiconductor chip 200, the heat generated from the second semiconductor chip 400 may be rapidly dissipated outside through the first semiconductor chip 200. As the first adhesion pattern 310 decreases in volume, the heat generated from the second semiconductor chip 400 may be more rapidly dissipated. According to embodiments, the number of the first adhesion pattern 310, a shape of plane of the first adhesion pattern 310, and a height of the first adhesion pattern 310 are adjusted to improve the heat dissipation characteristic.

The second adhesion pattern 320 may be provided on the top surface 200a and a side surface 400c of the second semiconductor chip 400. The second adhesion pattern 320 may include the same material as the first adhesion pattern 310. As illustrated in FIG. 1A, the second adhesion pattern 320 may not overlap the second semiconductor chip 400. The second adhesion pattern 320 may be disposed to be laterally spaced apart from the first adhesion pattern 310.

FIG. 1C is a cross-sectional view taken along line A-B of FIG. 1A according to another embodiment of the inventive concept.

Referring to FIG. 1C, a semiconductor device 2 may include a first semiconductor chip 200, a first adhesion pattern 310, a second adhesion pattern 320, and a second semiconductor chip 400. The first semiconductor chip 200 may be the same as described in FIGS. 1A and 1B. The first semiconductor chip 200 may have a recess portion 201 in a top surface 200a thereof. The first adhesion pattern 310 may extend to the top surface 200a of the first semiconductor chip 200 within the recess portion 201. The first adhesion pattern 310 may be connected to the second adhesion pattern 320 and include the same material as the second adhesion pattern 320. Here, the first adhesion pattern 310 may be disposed on a bottom surface 400b, and the second adhesion pattern 320 may be disposed on the side surface 400c. The second semiconductor chip 400 may be provided on the first semiconductor chip 200. The second semiconductor chip 400 may physically contact the first adhesion pattern 310. As a portion of the first adhesion pattern 310 between the top surface 200a of the first semiconductor chip and the bottom surface 400b of the second semiconductor chip 400 decreases in thickness D, heat generated from the second semiconductor chip 400 may be rapidly transferred to the first semiconductor chip 200. The recess portion 201 may be provided to reduce a thickness D of the adhesion pattern on the top surface 200a of the first semiconductor chip 200. Therefore, heat dissipation characteristic of the second semiconductor chip 400 may be improved.

FIG. 1D is a cross-sectional view taken along line A-B of FIG. 1A according to another embodiment of the inventive concept. Hereinafter, the duplicated descriptions, which have been described already, will be omitted.

Referring to FIG. 1D together with FIG. 1A, a semiconductor device 3 may include a first semiconductor chip 200, a first adhesion pattern 310, a second semiconductor chip 400, and a second adhesion pattern 320. The second semiconductor chip 400 may be provided on the first semiconductor chip 200. A recess portion 401 may be provided in a bottom surface 400b of the second semiconductor chip 400. The first adhesion pattern 310 may be provided within the recess portion 401 between the first semiconductor chip 200 and the second semiconductor chip 400. The second semiconductor chip 400 may be attached to the first semiconductor chip 200 by the first adhesion pattern 310. The first adhesion pattern 310 may be localized within the recess portion 401 to expose the bottom surface 400b of the second semiconductor chip 400. The second semiconductor chip 400 may physically contact a top surface 200a of the first semiconductor chip 200.

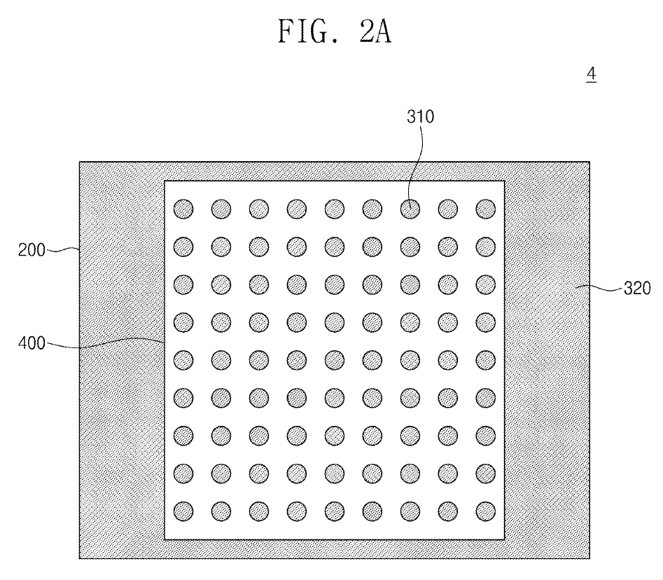

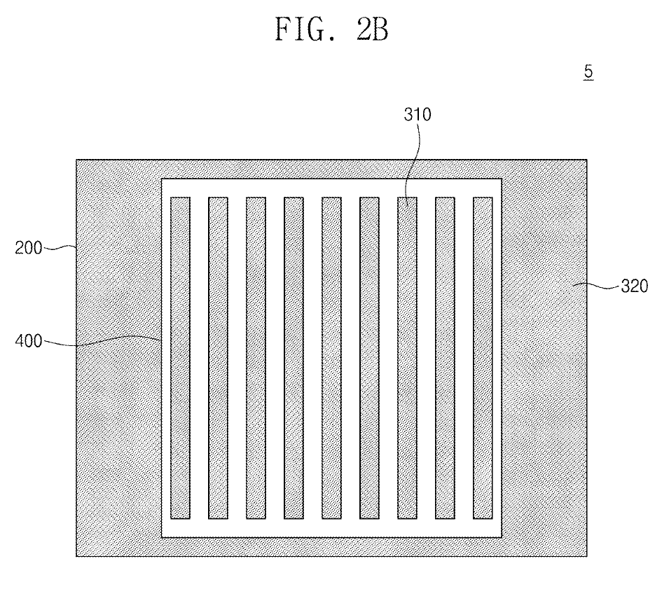

FIGS. 2A and 2B are plan views of first adhesion patterns according to other embodiments. Hereinafter, the duplicated descriptions, which have been described already, will be omitted.

Referring to FIGS. 2A and 2B together with FIG. 1B, semiconductor devices 4 and 5 may include a first semiconductor chip 200, a first adhesion pattern 310, a second semiconductor chip 400, and a second adhesion pattern 320. The first adhesion pattern 310 may overlap the second semiconductor chip 400. The first adhesion pattern 310 may have a circular shape in view of plane as illustrated in FIG. 2A. According to another embodiment, the first adhesion pattern 310 may extend in one direction in view of plane as illustrated in FIG. 2B. However, the embodiment is not limited to a planar shape of the first adhesion pattern 310. For example, the first adhesion pattern 310 may have various shapes.

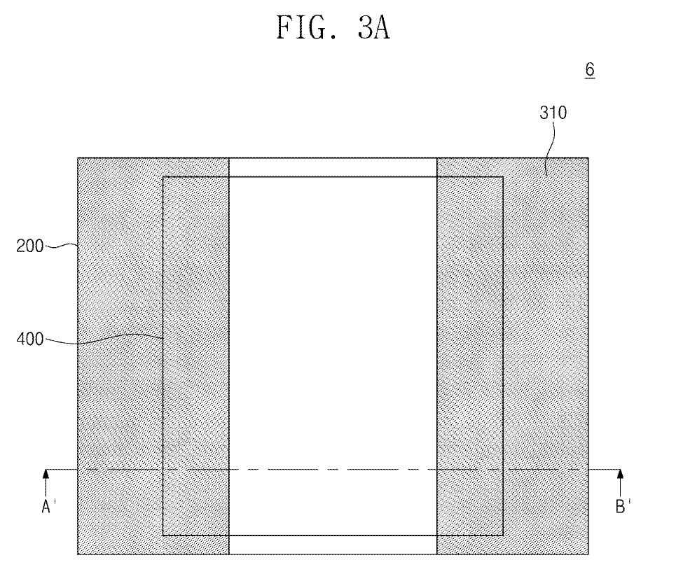

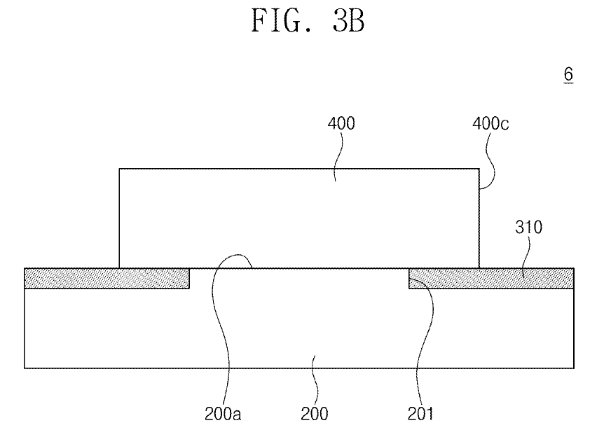

FIG. 3A is a plan view of a semiconductor device according to another embodiment of the inventive concept. FIG. 3B is a cross-sectional view taken along line A′-B′ of FIG. 3A. Hereinafter, the duplicated descriptions, which have been described already, will be omitted.

Referring to FIGS. 3A and 3B, a semiconductor device 6 may include a first semiconductor chip 200, a first adhesion pattern 310, and a second semiconductor chip 400. The first semiconductor 200 may have a recess portion 201 in a top surface 200a thereof. The first adhesion pattern 310 may be provided within the recess portion 201. The first adhesion pattern 310 may be provided on an edge area of the first semiconductor chip 200. The first adhesion pattern 310 may expose the top surface 200a of a central area of the first semiconductor chip 200. The second semiconductor chip 400 may be provided on the first semiconductor chip 200. The second semiconductor chip 400 may physically contact each of the first adhesion pattern 310 and the first semiconductor chip 200. As illustrated in FIG. 3A, in view of plane, the second semiconductor chip 400 may overlap one portion of the first adhesion pattern 310 but not overlap the other portion of the first adhesion pattern 310. Unlike FIGS. 1A and 1B, the second adhesion pattern 320 may not provided.

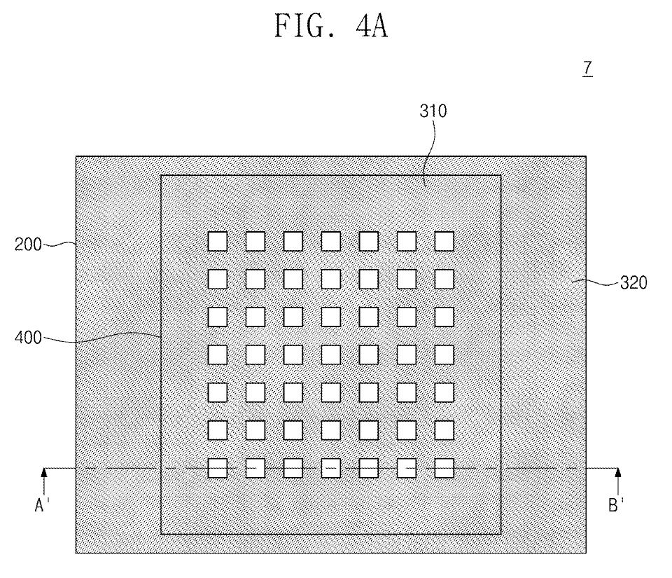

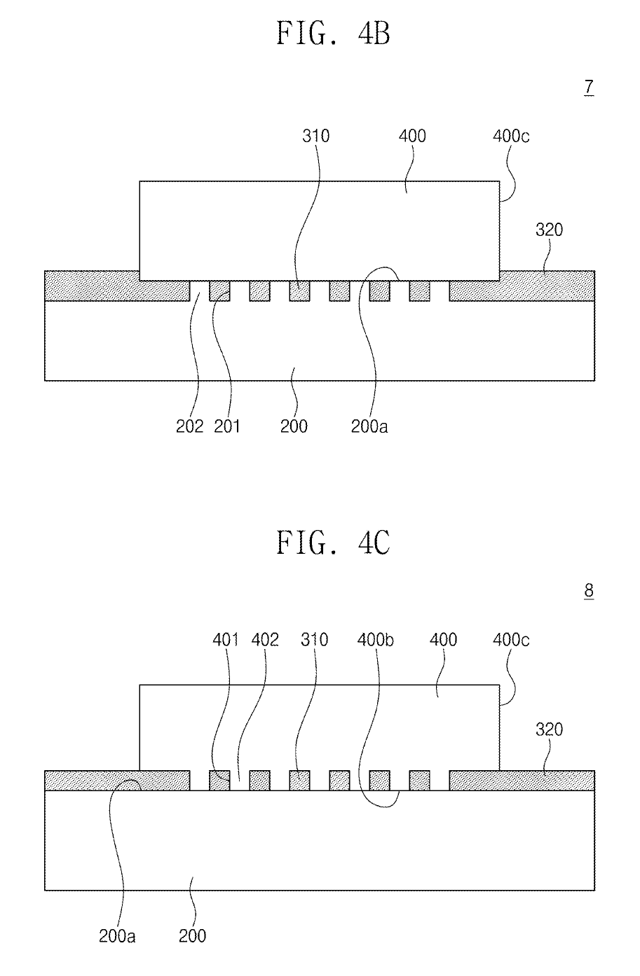

FIG. 4A is a plan view of a semiconductor device according to another embodiment of the inventive concept. FIG. 4B is a cross-sectional view taken along line A′-B′ of FIG. 4A. Hereinafter, the duplicated descriptions, which have been described already, will be omitted.

Referring to FIGS. 4A and 4B, a semiconductor device 7 may include a first semiconductor chip 200, a first adhesion pattern 310, and a second semiconductor chip 400. The first semiconductor 200 may have a recess portion 201 in a top surface 200a thereof. The recess portion 201 may define protruded portions 202. The protruded portions 202 may have circular shapes in a plan view. For another example, the protruded portions 202 may have quadrangle shapes, in a plan view. The first adhesion pattern 310 may be provided within the recess portion 201. The first adhesion pattern 310 may be connected to the second adhesion pattern 320 and include the same material as the second adhesion pattern 320.

The second semiconductor chip 400 may be provided on the first semiconductor chip 200. The second semiconductor chip 400 may physically contact each of the first adhesion pattern 310 and the first semiconductor chip 200.

FIG. 4C is a cross-sectional view taken along line A′-B′ of FIG. 4A according to another embodiment of the inventive concept.

Referring to FIG. 4C together with FIG. 4A, a semiconductor device 8 may include a first semiconductor chip 200, a first adhesion pattern 310, a second semiconductor chip 400, and a second adhesion pattern 320. A recess portion 401 may be provided in a bottom surface 400b of the second semiconductor chip 400. The first adhesion pattern 310 may be provided within the recess portion 401 between the first semiconductor chip 200 and the second semiconductor chip 400. The second semiconductor chip 400 may be attached to the first semiconductor chip 200 by the first adhesion pattern 310. The recess portion 401 may define protruded portions 402. The protruded portions 402 may have circular shapes in a plan view. The first adhesion pattern 310 may be connected to the second adhesion pattern 320 and include the same material as the second adhesion pattern 320.

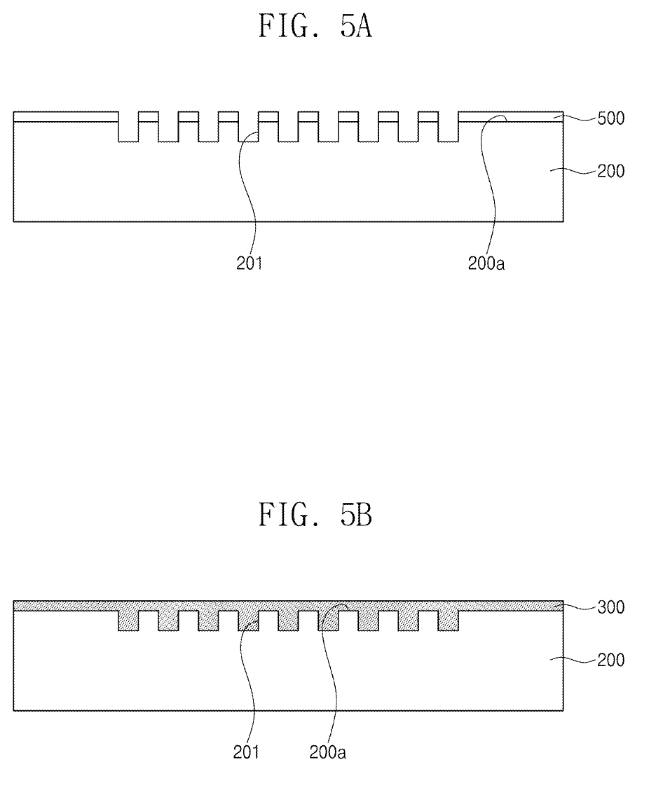

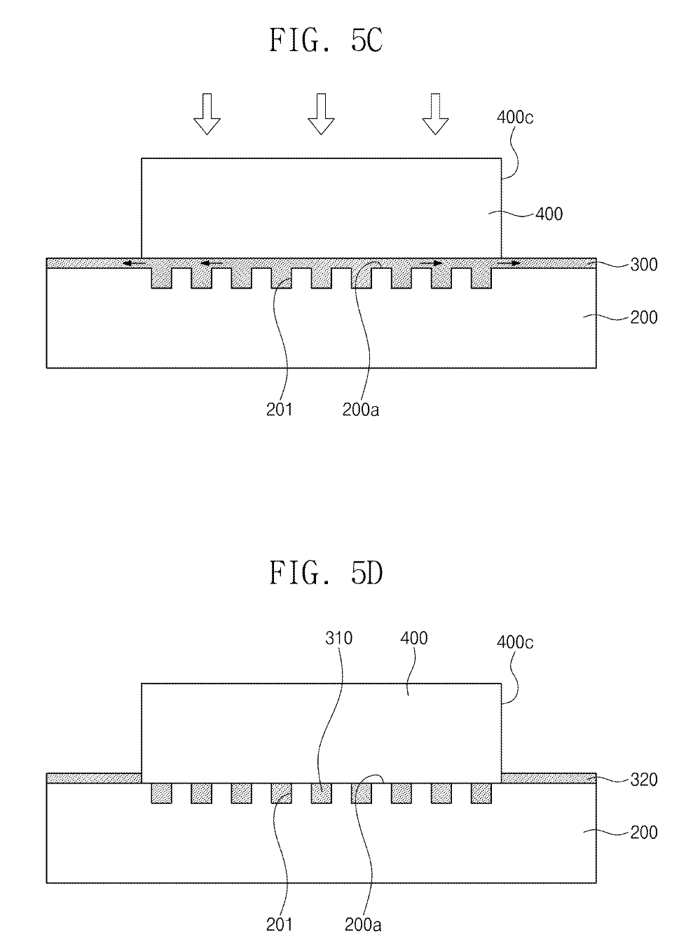

FIGS. 5A to 5E are cross-sectional views taken along line A-B of FIG. 1A for illustrating a method for manufacturing a semiconductor device according to an embodiment.

Referring to FIG. 5A together with FIG. 1A, a mask pattern 500 may be provided on a first semiconductor chip 200. The mask pattern 500 may expose a top surface 200a of the first semiconductor chip 200. The first semiconductor chip 200 may be etched by using the mask pattern 500 to form a recess portion 201 on the top surface 200a of the first semiconductor chip 200. The first semiconductor chip 200 may be etched in a wet etch process or a dry etch process. The mask pattern 500 may be removed.

Referring to FIG. 5B with FIG. 1A, an adhesion pattern 300 is formed on the top surface 200a of the first semiconductor chip 200 to cover the top surface 200a of the first semiconductor chip 200. The adhesion pattern 300 may be filled within the recess portion 201.

Referring to FIGS. 5C and 5E in sequence, the second semiconductor chip 400 may be disposed on the adhesion pattern 300. The adhesion pattern 300 may have flowability. Until the second semiconductor chip 400 contacts the first semiconductor chip 200, a pressure may be applied to the second semiconductor chip 400. The adhesion pattern 300 between the top surface 200a of the first semiconductor chip 200 and a bottom surface 400b of the second semiconductor chip 400 may move toward a side surface 400c of the second semiconductor chip 400. Due to the pressure, a second adhesion pattern 320 may be separated from a first adhesion pattern 310 as illustrated in FIG. 5D. Accordingly, the first adhesion pattern 310 localized within the recess portion 201 may be formed. The first adhesion pattern 310 may not cover the top surface 200a of the first semiconductor chip 200. The second adhesion pattern 320 may be provided on the top surface 200a of the first semiconductor chip 200 and the side surface 400c of the second semiconductor chip 400. The first adhesion pattern 310 and the second adhesion pattern 320 may be cured by light or heat. The manufacturing of the semiconductor device 1 may be completed through the foregoing embodiment.

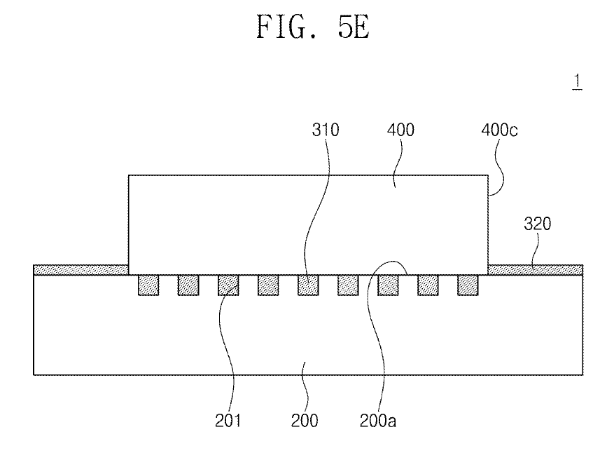

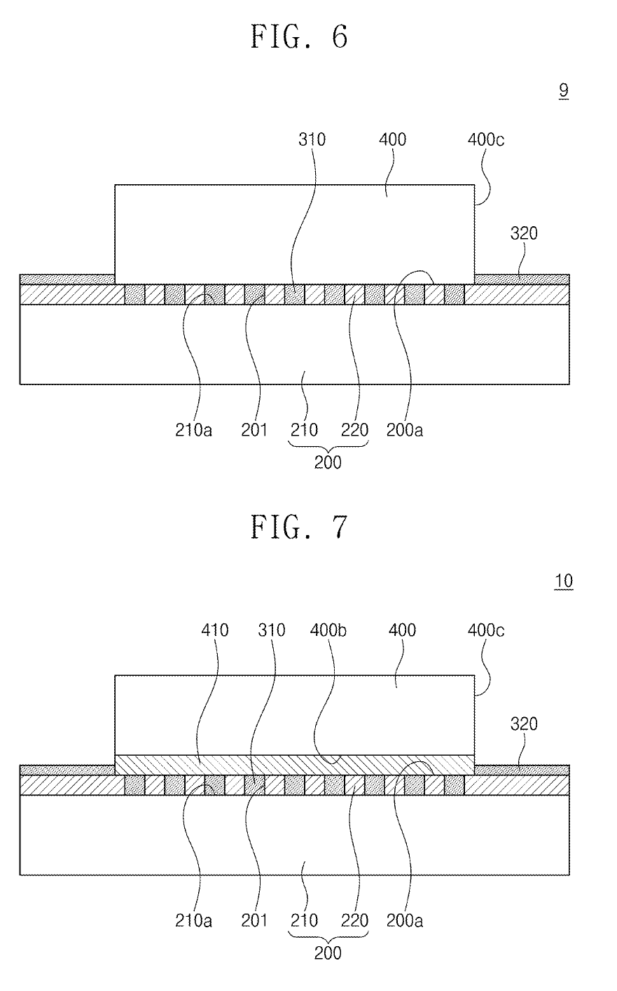

FIG. 6 is a cross-sectional view taken along line A-B of FIG. 1A for illustrating a semiconductor device according to another embodiment. Hereinafter, the duplicated descriptions, which have been described already, will be omitted.

Referring to FIG. 6 together with FIG. 1A, a semiconductor device 9 may include a first semiconductor chip 200, a first adhesion pattern 310, a second semiconductor chip 400, and a second adhesion pattern 320. The first semiconductor chip 200 may include a base layer 210 and a metal pattern 220 on the base layer 210. The base layer 210 may include bulk silicon, silicon on insulator (SOI), or III-V compound semiconductor. The base layer 210 may have a thermal conductivity of about 149 W/mk (in the case of silicon). The metal pattern 220 may be disposed on a top surface 200a of the first semiconductor chip 200. The metal pattern 220 may have a thermal conductivity of about 400 W/mk or more. The metal pattern 220 may contain gold (Au), silver (Ag), aluminum (Al), titanium (Ti), or alloy thereof. A recess portion 201 may be provided within the metal pattern 220 to expose a top surface 210a of the base layer 210. The first adhesion pattern 310 may be provided within the recess portion 201 to expose a top surface of the metal pattern 220. Here, the top surface of the metal pattern 220 may represent the top surface 200a of the first semiconductor chip 200. The first adhesion pattern 310 may include one of materials explained in FIGS. 1A and 1B. For another example, the first adhesion pattern 310 may have a shape as described in an example of FIG. 2A, an example of FIG. 2B, or examples of FIGS. 3A and 3B, examples of FIGS. 4A and 4B or examples of FIG. 4C.

The second semiconductor chip 400 may be provided on the first semiconductor chip 200 and the first adhesion pattern 310. The second semiconductor chip 400 may physically contact each of the metal pattern 220 and the first adhesion pattern 310. As the first semiconductor chip 200 has a thermal conductivity greater than that of the first adhesion pattern 310, heat of the second semiconductor chip 400 may be more rapidly transferred to the first semiconductor chip 200. According to the embodiments, the metal pattern 220 may have a thermal conductivity greater than those of the first adhesion pattern 310 and the base layer 210, respectively. Therefore, heat dissipation characteristic of the second semiconductor chip 400 may be further improved by the metal pattern 220.

FIG. 7 is a cross-sectional view taken along line A-B of FIG. 1A for illustrating a semiconductor device according to another embodiment. Hereinafter, the duplicated descriptions, which have been described already, will be omitted.

Referring to FIG. 7 together with FIG. 1A, a semiconductor device 10 may include a first semiconductor chip 200, a first adhesion pattern 310, a second semiconductor chip 400, and a second adhesion pattern 320. The first semiconductor chip 200, the first adhesion pattern 310 and the second semiconductor chip 400 may be the same as described in FIG. 6. For example, the first semiconductor chip 200 may include a base layer 210 and a metal pattern 220. A recess portion 201 may be provided within the metal pattern 220. The first adhesion pattern 310 may be provided within the recess portion 201. The first adhesion pattern 310 may expose a top surface 200a of the first semiconductor chip 200. The first semiconductor chip 310 may have a thermal conductivity of about 0.5 W/mK.

A metal layer 410 may be interposed between the first semiconductor chip 200 and the second semiconductor chip 400. The metal layer 410 may physically contact each of the metal pattern 220 and the first adhesion pattern 310. For example, the metal layer 410 may have a thermal conductivity of about 400 W/mK or more. The metal layer 410 may contain gold (Au), silver (Ag), aluminum (Al), titanium (Ti), or alloy thereof.

The second semiconductor chip 400 may be disposed on the metal layer 410. The metal layer 410 may have a thermal conductivity greater than that of the first adhesion pattern 310. As a contact area between the second semiconductor chip 400 and the metal layer 410 increases, heat generated from the second semiconductor chip 400 may be rapidly dissipated. The second semiconductor chip 400 may have a bottom surface 400b that physically contacts the metal layer 410 but does not contact the first adhesion pattern 310. When the second semiconductor chip 400 operates, the heat generated from the second semiconductor chip 400 may be rapidly transferred to the metal layer 410. The heat transferred to the metal layer 410 may be dissipated outside through the metal pattern 220 and the base layer 210. According to the embodiments, the heat dissipation characteristic of the second semiconductor chip 400 may be further improved.

According to other embodiments, the metal pattern 220 may be omitted, and the recess portion 201 may be formed within the base layer 210. In this case, the metal layer 410 may contact each of the base layer 210 of the first semiconductor chip 200 and the first adhesion pattern 310.

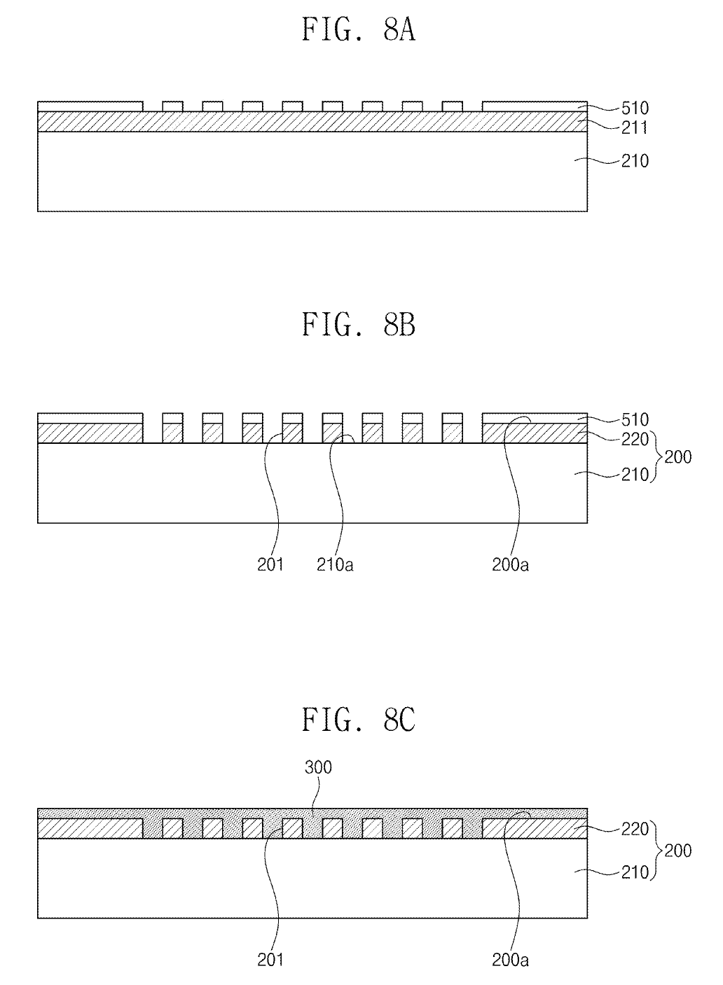

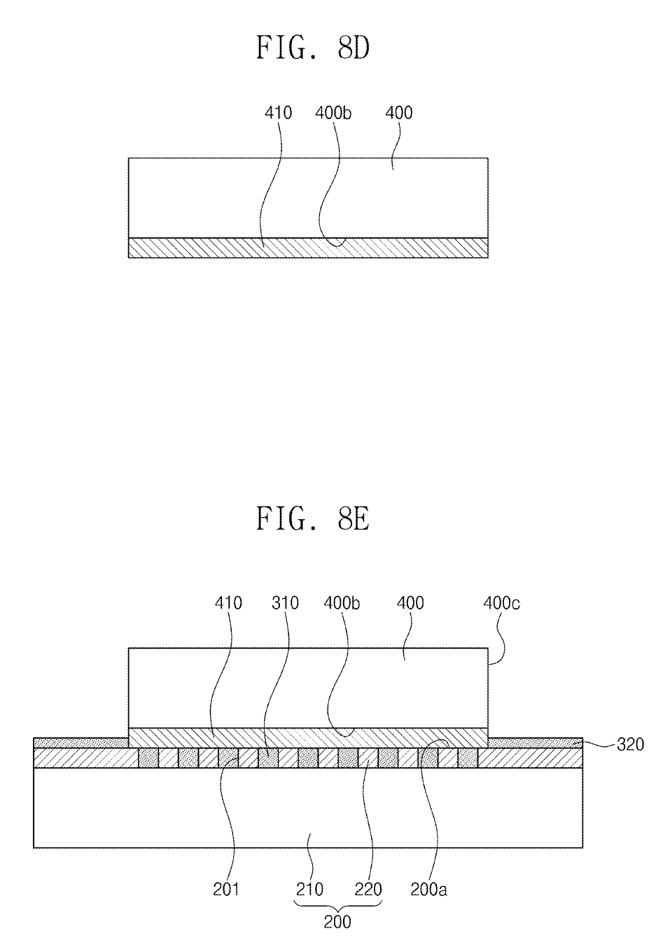

FIGS. 8A to 8E are cross-sectional views taken along line A-B of FIG. 1A for illustrating a method for manufacturing a semiconductor device according to another embodiment. Hereinafter, the duplicated descriptions, which have been described already, will be omitted.

Referring to FIG. 8A, a conductive layer 211 and a mask layer 510 may be formed on a base layer 210. The conductive layer 211 may be formed by a deposition process. The mask layer 510 may be formed on the conductive layer 211 to expose a top surface of the conductive layer 211.

Referring to FIG. 8B, the conductive layer 211 may be etched by using the mask layer 510 to form a metal layer 220. The metal pattern 220 may have a recess portion 201. The conductive layer 211 may be etched in a wet etch process or a dry etch process. The conductive layer 211 may be etched until the recess portion 201 exposes a top surface 210a of the base layer 210. Accordingly, the first semiconductor chip 200 including the base layer 210 and the metal pattern 220 may be manufactured. Thereafter, the mask pattern 510 may be removed.

Referring to FIG. 8C, an adhesion pattern 300 is formed on a top surface 200a of the first semiconductor chip 200 and filled in the recess portion 201. The adhesion pattern 300 may cover the top surface 200a of the first semiconductor chip 200. The adhesion pattern 300 may be formed by the same method as described in FIG. 5B.

Referring to FIG. 8D, a metal layer 410 may be formed on a bottom surface 400b of a second semiconductor chip 400. The metal layer 410 may be formed by a deposition process. The metal layer 410 may contain gold (Au), silver (Ag), aluminum (Al), titanium (Ti), or alloy thereof.

Referring to FIG. 8E together with FIG. 8C, the second semiconductor chip 400 may be disposed on the adhesion pattern (see reference numeral 300 in FIG. 8C) so that the metal layer 410 faces the first semiconductor chip 200. A pressure may be applied to the second semiconductor chip 400 to form a first adhesion pattern 310 and a second adhesion pattern 320. For example, the pressure may be applied until the second adhesion pattern 320 is separated from the first adhesion pattern 310. The adhesion pattern 300 between the top surface 200a of the first semiconductor chip 200 and the bottom surface 400b of the second semiconductor chip 400 may be moved to the second adhesion pattern 320, and thus the first adhesion pattern 310 may be localized within the recess portion 201. The metal layer 410 may contact the top surface 200a of the first semiconductor chip 200, for example, the metal pattern 220. The first adhesion pattern 310 and the second adhesion pattern 320 may be cured by light or heat. The manufacturing of the semiconductor device 10 explained in FIG. 7 may be completed through the above-described manufacturing examples. For another example, the forming process of the metal layer 410 of FIG. 8D may be omitted to manufacture the semiconductor device 9 of FIG. 6.

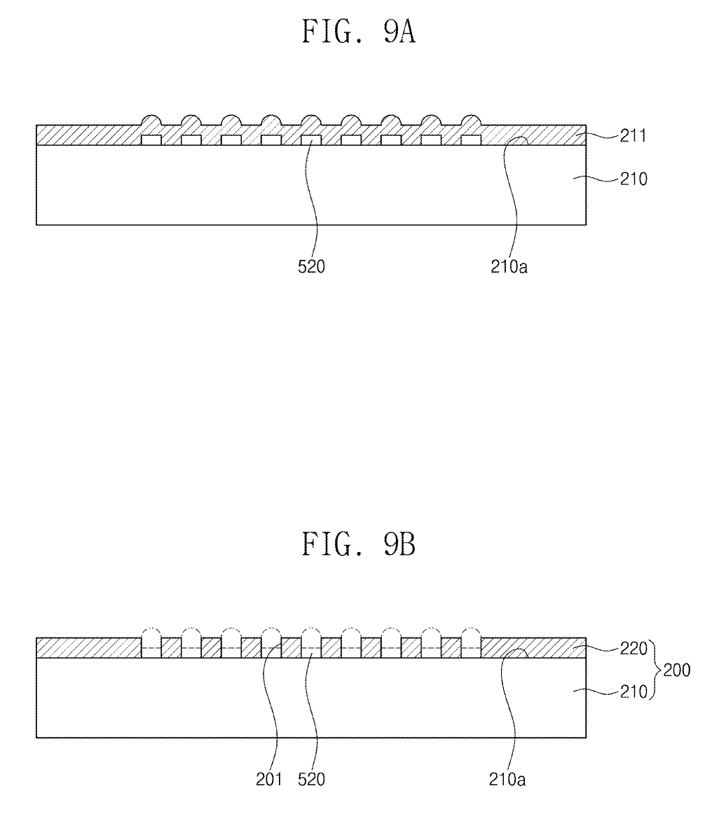

FIGS. 9A to 9B are cross-sectional views taken along line A-B of FIG. 1A for illustrating a method for forming a recess portion according to another embodiment.

Referring to FIG. 9A, a lift-off layer 520 may be formed on a base layer 210. The lift-off layer 520 may expose a top surface 210a of the base layer 210. A conductive layer 211 may be formed on the lift-off layer 520 to cover the top surface 210a of the base layer 210 exposed by the lift-off layer 520. The conductive layer 211 may be formed by a deposition process.

Referring to FIG. 9B, the lift-off layer 520 and the conductive layer 211 on the lift-off layer 520 may be removed to form a metal pattern 220. The metal pattern 220 may have a recess portion 201 that exposes the top surface 210a of the base layer 210. Accordingly, the first semiconductor chip 200 including the base layer 210 and the metal pattern 220 may be manufactured.

Referring to FIG. 8C again, the first adhesion pattern 310 may be provided on the first semiconductor chip 200 and filled in the recess portion 201. Here, the metal pattern 220 and the recess portion 201 may be formed as described in FIGS. 9A and 9B. Referring to FIG. 8D, the metal layer 410 may be deposited on the bottom surface of the second semiconductor chip 400. Referring to FIG. 8E, the second semiconductor chip 400 may be disposed on the first adhesion pattern 310 and the metal pattern 220. The manufacturing of the semiconductor device 10 explained in FIG. 7 may be completed through the above-described manufacturing examples. For another example, the forming process of the metal layer 410 of FIG. 8D may be omitted to manufacture the semiconductor device 9 of FIG. 6.

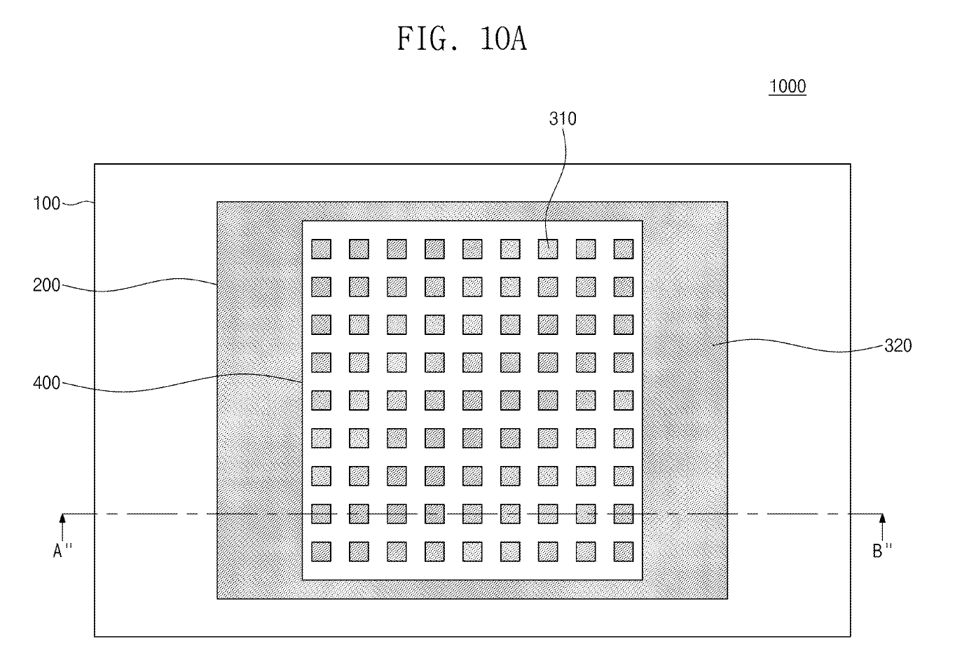

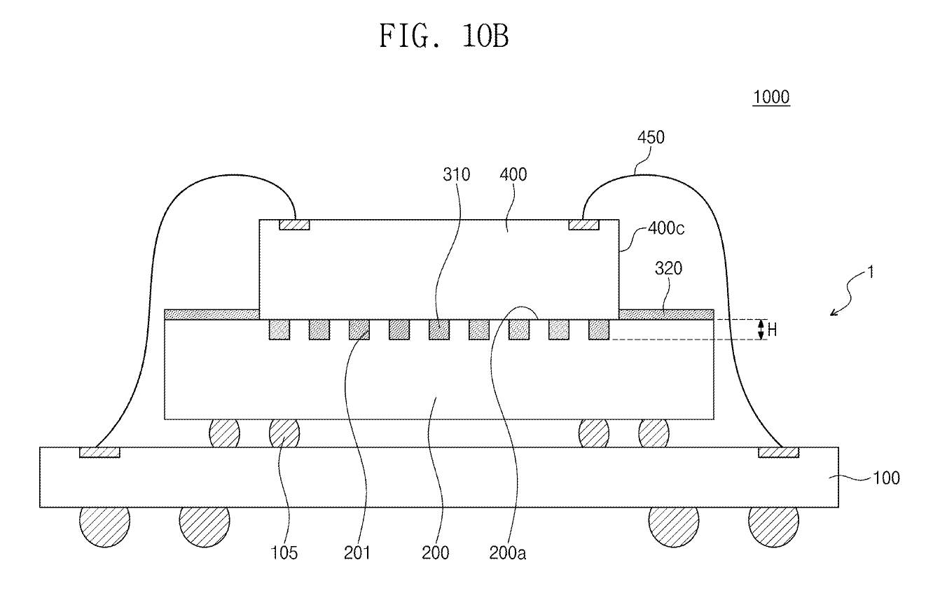

FIGS. 10A and 10B are cross-sectional views of a semiconductor package according to an embodiment. FIG. 10B is a cross-sectional view taken along line A″-B″ of FIG. 10A.

Referring to FIGS. 10A and 10B, a semiconductor package 1000 may include a substrate 100 and a semiconductor device 1 on the substrate 100. The substrate 100 may be a printed circuit board (PCB) including a circuit pattern. Here, the semiconductor device 1 of FIGS. 1A and 1B may be used. For example, the semiconductor device 1 may include a first semiconductor chip 200, a first adhesion pattern 310, and a second semiconductor chip 400. For another example, the semiconductor device 2 of FIG. 1C, the semiconductor device 3 of FIG. 1D, the semiconductor device 4 of FIG. 2A, the semiconductor device 5 of FIG. 2B, the semiconductor device 6 of FIGS. 3A and 3B, the semiconductor device 7 of FIGS. 4A and 4B, the semiconductor device 8 of FIG. 4C, the semiconductor device 9 of FIG. 6, or the semiconductor device 10 of FIG. 7 may be provided on the substrate 100 to manufacture the semiconductor package. In this case, the first semiconductor chip 200 may face the substrate 100. The connecting terminal 105 may be interposed between the substrate 100 and the first semiconductor chip 200 to electrically connect the first semiconductor chip 200 to the substrate 100. The connecting terminal 105 may include a conductive material and have a shape of a solder or a bump. For another example, the first semiconductor chip 200 may be electrically connected to the substrate 100 through a bonding wire (not shown). In this case, a top surface 200a of the first semiconductor chip 200 may serve as an active surface.

The second semiconductor chip 400 may be electrically connected to the substrate 100 through a bonding wire 450. Unlike the drawings, the second semiconductor chip 400 may be a flip chip device face-down mounted on the first semiconductor chip 200.

A molding film (not show) may be further provided on the substrate 100 to cover the first semiconductor chip 200 and the second semiconductor chip 400.

According to the embodiment of the inventive concept, the adhesion pattern may be provided within the recess portion. When the second semiconductor chip operates, heat may be generated in the second semiconductor chip. The first semiconductor chip may have a thermal conductivity higher than that of the first bonding pattern. Therefore, the heat generated from the second semiconductor chip may be rapidly dissipated outside through the first semiconductor chip and the substrate. As the first adhesion pattern decreases in volume, the heat generated from the second semiconductor chip may be more rapidly dissipated. Accordingly, the heat dissipation characteristic of the second semiconductor chip may be improved.

What is claimed is:

1. A semiconductor device comprising:
a first semiconductor chip having a recess portion in one surface thereof;
a first adhesion pattern filled within the recess portion of the first semiconductor chip; and
a second semiconductor chip attached to the first semiconductor chip by the first adhesion pattern,
wherein the first adhesion pattern is disposed between the first semiconductor chip and the second semiconductor chip.

2. The semiconductor device of claim 1, wherein the second semiconductor chip physically contacts the first adhesion pattern and the first semiconductor chip.

3. The semiconductor device of claim 1, wherein the first semiconductor chip has a thermal conductivity greater than that of the first adhesion pattern.

4. The semiconductor device of claim 1, wherein the first semiconductor chip further comprises a metal pattern,
wherein the recess portion is disposed within the metal pattern.

5. The semiconductor device of claim 4, wherein the second semiconductor chip physically contacts the metal pattern and the first adhesion pattern.

6. The semiconductor device of claim 1, further comprising a metal layer interposed between the first adhesion pattern and the second semiconductor chip,
wherein the metal layer has a thermal conductivity greater than that of the first adhesion pattern.

7. The semiconductor device of claim 1, further comprising a second adhesion pattern disposed on the one surface of the first semiconductor chip and a side surface of the second semiconductor chip,
wherein the second adhesion pattern comprises the same material as the first adhesion pattern.

8. The semiconductor device of claim 1, wherein the recess portion has a height of about 100 nm to about 10 μm.

9. The semiconductor device of claim 1, further comprising a substrate,
wherein the first semiconductor chip is disposed on the substrate.

10. A method for manufacturing a semiconductor device, the method comprising:
preparing a first semiconductor chip having a recess portion in one surface thereof;
forming an adhesion pattern within the recess portion; and
disposing a second semiconductor chip on the first semiconductor chip and the adhesion pattern.

11. The method of claim 10, wherein the second semiconductor chip contacts the adhesion pattern and the first semiconductor chip, and
the first semiconductor chip has a thermal conductivity greater than that of the adhesion pattern.

12. The method of claim 10, wherein the preparing of the first semiconductor chip comprises:
forming a mask pattern on the one surface of the first semiconductor chip; and
etching the first semiconductor chip exposed by the mask pattern to form the recess portion.

13. The method of claim 10, wherein the forming of the adhesion pattern comprises applying the adhesion pattern on the first semiconductor chip to cover the one surface of the first semiconductor chip.

14. The method of claim 13, further comprising applying a pressure to the second semiconductor chip to allow a bottom surface of the second semiconductor chip to physically contact the one surface of the first semiconductor chip after the disposing the second semiconductor chip.

15. The method of claim 10, further comprising disposing the first semiconductor chip on a substrate.
